(19) United States
(12) Patent Application Publication
(10) Pub. No.: US 2017/0323765 A1
(43) Pub. Date: Nov. 9, 2017

(54) APPARATUS FOR PLASMA TREATING AND PROCESS FOR PRODUCING MODIFIED PROTEIN STRUCTURE

(71) Applicant: Stephen James Motosko, III, Sarasota, FL (US)

(72) Inventor: Stephen James Motosko, III, Sarasota, FL (US)

(21) Appl. No.: 15/628,063

(22) Filed: Jun. 20, 2017

Related U.S. Application Data
(63) Continuation-in-part of application No. 15/009,264, filed on Jan. 28, 2016.
(60) Provisional application No. 62/108,798, filed on Jan. 28, 2015.

(51) Int. Cl. H01J 37/32

(52) U.S. Cl. CPC H01J 37/32009; H01J 37/3244; H05H 2240/10

(57) ABSTRACT

A protein powder is exposed to plasma at a specified temperature and power for a specified time period wherein the plasma treated protein powder includes an increased fluorescence in a melt curve at room temperature in comparison to an untreated protein.

### CROSS-REFERENCE TO RELATED APPLICATIONS

This Application claims the benefit of U.S. Provisional Application 62/108,798 filed on Jan. 28, 2015, and U.S. patent application Ser. No. 15/009,264 filed Jan. 28, 2016 the contents of which are incorporated herein in their entirety.

### FIELD

The present application relates generally to plasma treatment. More specifically, the present application relates to a method and apparatus and plasma treated protein powder.

### BACKGROUND

Gas plasma treatment allows for molecular engineering of materials to impart unique characteristics and surface properties without affecting the bulk properties of the whole material. It is known to utilize plasma treatments for various surfaces to improve surface adhesion between multiple pieces. It is commonly used before printing, bonding, painting, varnishing, and coating processes. Furthermore, protein powders and vitamin supplements are well known in the art to provide nutrients to athletes to supplement the missing vitamins and nutrients in their diet. Accordingly, there exists a need in the art to provide a vitamin supplement or protein powder with improved absorption characteristics.

### SUMMARY

In one aspect there is disclosed a protein powder exposed to plasma at a specified temperature and power for a specified time period wherein the plasma treated protein powder includes an increased fluorescence in a melt curve at room temperature in comparison to an untreated protein.

In another aspect there is disclosed a plasma treated orally ingested protein powder composition having a protein powder exposed to plasma at a specified temperature and power for a specified time period wherein the plasma treated protein powder includes an increased fluorescence in a melt curve at room temperature in comparison to an untreated protein for use in the improvement of a muscle function in a mammal.

In a further aspect there is disclosed a method of increasing muscle protein comprising administering to a subject a protein powder exposed to plasma at a specified temperature and power for a specified time period wherein the plasma treated protein powder includes an increased fluorescence in a melt curve at room temperature in comparison to an untreated protein.

These and additional features provided by the embodiments described herein will be more fully understood in view of the following detailed description, in conjunction with the drawings.

### BRIEF DESCRIPTION OF THE DRAWINGS

The embodiments set forth in the drawings are illustrative and exemplary in nature and not intended to limit the subject matter defined by the claims. The following detailed description of the illustrative embodiments can be understood when read in conjunction with the following drawings, where like structure is indicated with like reference numerals and in which:

FIG. 1 illustrates a partially exploded perspective view of the apparatus of the in accordance with one or more embodiments shown and described herein;

FIG. 2 illustrates a perspective view of the adjustable cutoff flow control valve in accordance with one or more embodiments shown and described herein;

FIG. 3 illustrates an assembled perspective view of the apparatus in accordance with one or more embodiments shown and described herein;

FIG. 4 illustrates a perspective view of the adjustable cutoff flow control valve in accordance with one or more embodiments shown and described herein;

FIG. 5 illustrates an plan view of an embodiment of the plasma apparatus in accordance with one or more embodiments shown and described herein;

FIG. 6 illustrates an plan view of an embodiment of an angled plasma apparatus in accordance with one or more embodiments shown and described herein; and

FIG. 7 illustrates an plan view of an embodiment of an upright plasma apparatus in accordance with one or more embodiments shown and described herein;

FIG. 8 is a plot of the hydrophobicity of various treated protein powder samples;

FIG. 9A-H is a plot of the melt curves for treated WPI protein at various parameters;

FIG. 10 is a plot of the melt curve of treated and untreated WPI protein;

FIG. 11 is a plot of the melt curve of treated WPI protein at 25% humidity;

FIG. 12 is a plot of the melt curve of treated Casein protein;

FIG. 13 is a plot of the melt curve of treated Soy protein;

FIG. 14 is a plot of the melt curve of treated Sacha Inchin protein;

FIG. 15 is a plot of the melt curve of treated Rice protein;

FIG. 16 is a plot of the melt curve of treated Pea protein;

FIG. 17 is a plot of the suspended protein content of a treated and untreated sample;

FIG. 18 is a plot of the solubility of a treated and untreated sample;

FIG. 19 is CD plot of a treated and untreated sample;

FIG. 20 is CD plot of a treated and untreated sample;

FIG. 21 is CD plot of a treated and untreated sample;

FIG. 22 is CD plot of a treated and untreated sample;

FIG. 23 is a plot of the surface area of a treated and untreated sample;

FIG. 24 is a plot of the Muscle gain of a subject of a treated and untreated sample;

FIG. 25 is a plot of the fat loss of a subject of a treated and untreated sample;

FIG. 26 is a plot of the gastrointestinal distress of a treated and untreated sample;

FIG. 27 is a plot of the stomach comfort of a treated and untreated sample;

FIG. 28 is a plot of the mixability of a treated and untreated sample;

FIG. 29 is a plot of the muscle recovery of a treated and untreated sample;

FIG. 30 is a plot of the squat increase of a treated and untreated sample;

FIG. 31 is a plot of the bench press increase of a treated and untreated sample;

FIG. 32 is a plot of the protocol for a clinical study of treated and untreated protein compositions;

FIG. 33 is a table detailing parameters for a clinical study of treated and untreated protein compositions;

FIG. 34 is a table detailing parameters for a clinical study of treated and untreated protein compositions;

FIG. 35 is a plot of the percentage of proteins consumed in the clinical trial of FIG. 21;

FIG. 36 is a plot of the RMR of the clinical trial of FIG. 21;

FIG. 37 is table of strength parameters for treated and non-treated WPI in subjects in a clinical trial;

FIG. 38 is table of body parameters for treated and non-treated WPI in subjects in a clinical trial.

### DETAILED DESCRIPTION OF THE PREFERRED EMBODIMENTS

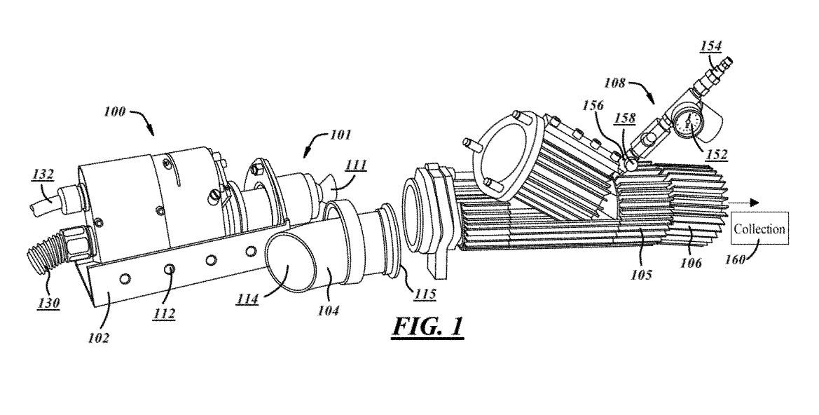

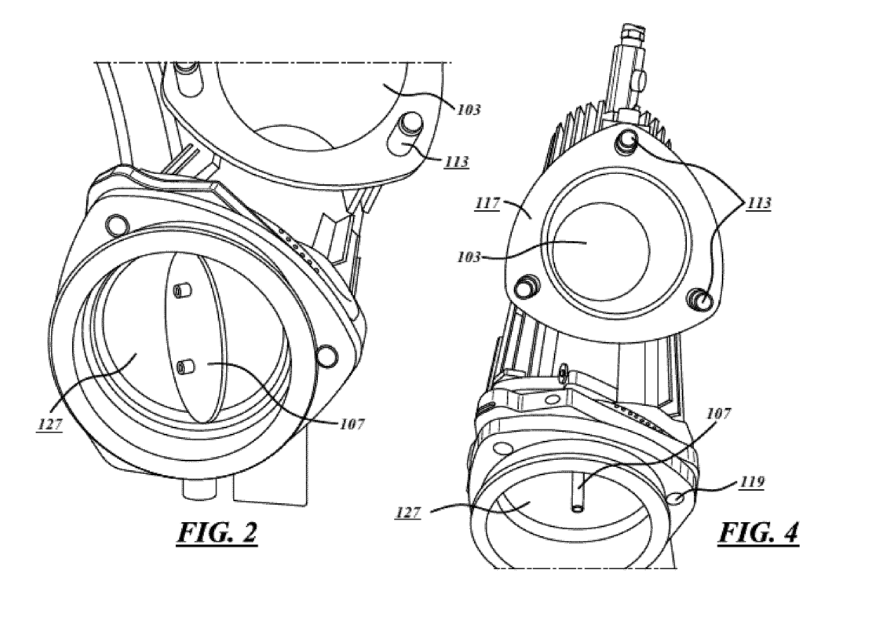

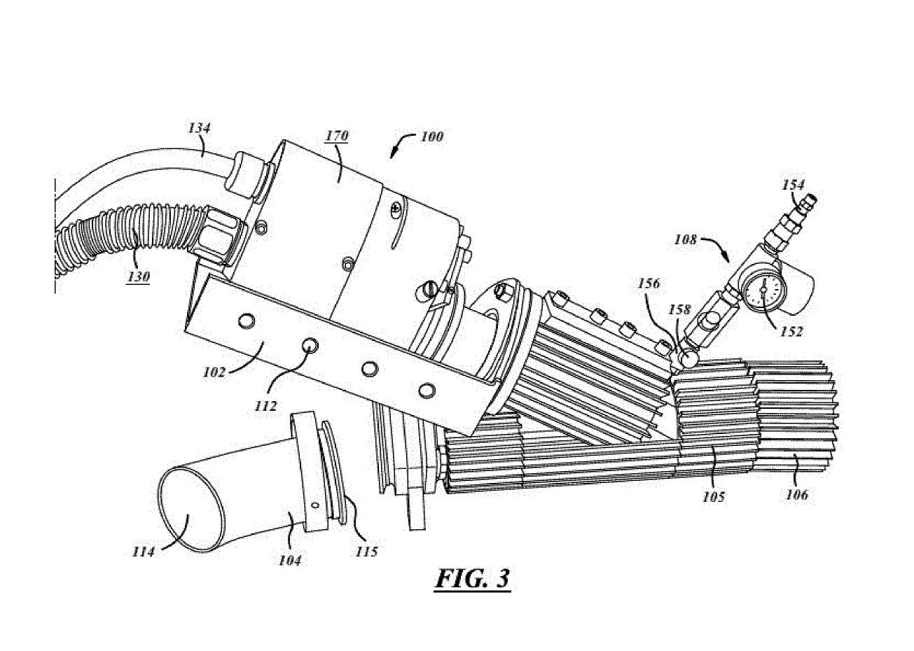

In the present embodiment, a gas plasma treating is utilized in a method and apparatus of treating a vitamin or mineral supplement, such as a protein powder. The surface treatment and/or etching apparatus as illustrated in FIGS. 1-7 is adapted for use to treat a protein powder with plasma surface etching. Gas plasma allows for molecular engineering of materials to impart unique characteristics and surface properties without affecting the bulk properties of the whole material. The use of plasma in the present invention may change the surface characteristics such as changes in biocompatibility, surface energy, morphology, texture, and absorption.

In the present embodiment, application of plasma to powder, specifically protein powder supplements, significantly increases absorption and digestibility factors (increase solubility by 71%, hydrophobicity by 27% and surface Area by 26%). Protease (which breaks down protein and allows your body to use it) such as Pepsin, Chymotrypsin, Serine and Elastase are most effective on hydrophobic amino acids. When the current plasma treating process is used with protein powder, hydrophobicity is increased by up to 27%. Supplementation allows the body to receive vitamins and minerals that are either lacking through diet or needed in excess of ordinary diet. By way of example, strength athletes frequently use protein powder which can help prepare damaged muscles that occur with weightlifting as well as the recovery period. In the present embodiment, this apparatus is used for plasma treating protein powders. However, this apparatus can be used with plasma treating any powder, granular or powder-like material.

In one embodiment, the plasma used is atmospheric pressure plasma. Atmospheric pressure plasma is a plasma which the pressure approximately matches that of the surrounding atmosphere. Atmospheric pressure plasma allows for a variety of characteristics including activation and etching. In other embodiments of the present invention, various other types of plasma may also be used such as corona treatment, corona discharge, flame plasma, chemical plasma, dielectric-barrier discharge, or partial discharge. The present embodiment utilizes a plasma plume incorporated within the apparatus.

The apparatus of the present invention is depicted in FIGS. 1-7 in accordance with one or more embodiments. The plasma generator 100 includes a plasma generator head 101. The plasma generator head 101 includes the plume producer 111 to produce a plume required for atmospheric pressure plasma application. The apparatus 100 further includes a mounting bracket 102 having mounting apertures 112. The mounting bracket 102 allows the apparatus to be mounted to a flat surface allowing for an upright configuration during plasma treatment. The upright configuration allows for utilizing gravity as the powder or other supplement flows through the main powder inlet tube 104. The powder inlet tube includes apertures 114, 115 leading to a central bore extending through the powder inlet tube 104. Alternatively, the bracket 102 can be angled.

In one embodiment, protein powder (or any other powder or granule) is introduced into the system at an angle. By controlling the angle of the entire assembly, the speed of the powder flow can also be controlled. Accordingly, the main mounting bracket 102 is adjustable to allow adjustment of the angle of the powder inlet tube 104.

The plasma/air orifice 103 provides for a rotating head which aerates the powder with compressed air during and before exposure to the plasma plume. The plasma/air orifice 103 allows for a larger area of the protein powder to be exposed during plasma treatment. The plasma/air orifice 103 includes an outer surface 117 have connection portions 113 to connect to the remainder of the apparatus.

The plasma reaction chamber 105 is provided at a lower end of the apparatus 100. The main reaction chamber 105 is where the protein powder from the inlet tube 104 connects with the plasma plume in the plasma generator head 101. A secondary airflow control 108 is further provided in fluid communication with the plasma generator head 101. The secondary airflow control 108 prevents powder from backing up in the plasma generator head. The secondary airflow control 108 puffs and aerates the powder during the plasma treating process. Furthermore, the secondary airflow control increases exposure of the protein powder to the plasma thus increasing the quality of the finished protein powder. The control 108 includes a connector 158 having a adjuster 158, a connector 154 and a data output 152.

An adjustable cutoff control valve 107 is also provided. The control valve 107 includes a “flapper” which prevents fast flow of air through the system. The valve includes an inlet 127 and corresponding connection portion 119.

Furthermore, a main airflow control 109 is provided to control the flow of air and protein powder through the system. It is crucially important to provide a constant flow of steady air while not having the air move too fast through the system.

The above apparatus for treating supplement powder (by surface treating and/or etching) may also be provided to other supplements in various forms (powder, pills, tablets, etc.) to increase absorption characteristics.

In yet another embodiment of the present invention, gas plasma treating is utilized in a method and apparatus of treating a vitamin or mineral supplement. The surface treatment and/or etching may also be utilized in the present embodiment. Gas plasma allows for molecular engineering of materials to impart unique characteristics and surface properties without affecting the bulk properties of the whole material. The use of plasma in the present invention may change the surface characteristics such as changes in biocompatibility, surface energy, morphology, texture and absorption. Supplementation allows the body to receive vitamins and minerals that are either lacking through diet or needed in excess of an ordinary diet. By way of example, strength athletes frequently use protein powder which can help repair damage to muscles that can occur with weight lifting as well as in the recovery period.

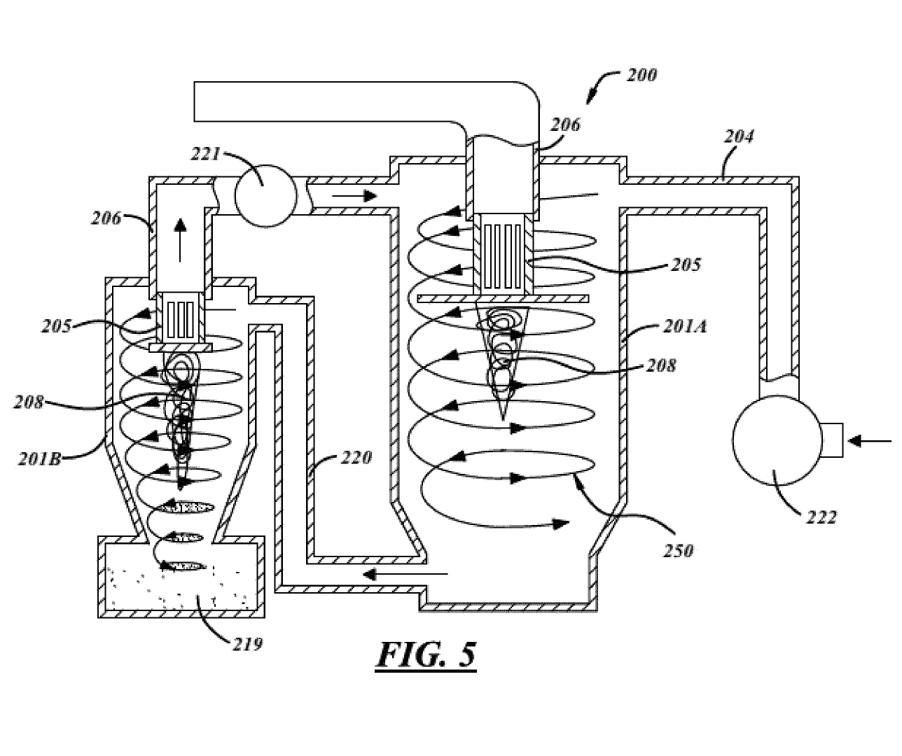

Plasma treating a supplement (by surface treating and/or etching) aids and expedites the digestion process by increasing bioavailability and absorption. It is estimated that one half of the US population produces insufficient stomach acid which diminishes the ability to absorb nutrients from food. Referring now to FIG. 5, an aerated method and apparatus 200 for exposing/treating supplement power to a plasma field is disclosed in the following:
a. Adding powder into a swirl cyclone chamber manually or via vacuum suction (through inlet 206);
b. Swirling the powder in the chambers 201A, 201B continuously for a predetermined amount of time to create a vortex 250 in the powder 219;
c. Injecting plasma (at reference numerals 205, 208) into the vortex of the swirling powder and/or injecting the plasma into the swirl stream or plasma field 250;
d. Optionally connecting multiple chambers for treatment with other gasses. Connecting these chambers in series (open air, argon, neon, inert gas . . . etc.) (through the inlets 206, 222 and tube 204); and
e. Sealing powder in individual pouches, vacuum pouches, capsules or other storage containers in an effort to reduce contamination.

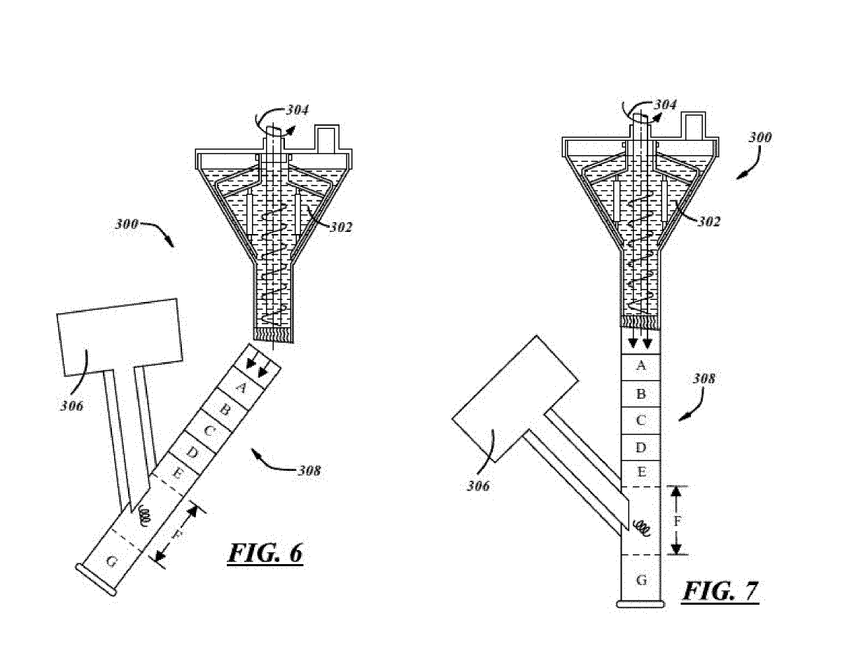

FIGS. 6 and 7 illustrate another embodiment and plan view of a plasma treating apparatus and corresponding method. The apparatus 300 includes a hopper 302 having a turning mechanism 304 for pushing the powder through the system. The system and method portion 308 includes a series of steps and method for plasma treating the powder or granules A-G.

Step A includes the gravity fed and air regulated flow rate. Current plasma reactor designs require large cycle times (upwards of 40 minutes) and depending on the underlying substrate may need to operate in a vacuum or with a non-atmospheric gas such as helium or argon. The present application discloses a novel reactor that allows a powder to be fed into the plasma chamber by gravity which allow for a faster cycle time while maintaining a controlled exposure and flow rate. For further control, an auger can be used to increase the plasma exposure time or conversely air pressure can be increased to lower the plasma exposure time. The unique reactor design also allows the air pressure in the reaction chamber to be independently controlled and maintained to impart unique characteristics on the underlying powder such as increasing the inherent surface area.

Step B includes the ability for vibration capability and a vibrator. When processing large volumes of powder, a common occurrence with a plasma reactor is jams or fine powders working their way into moving parts. The reactor allows for regular mechanical vibrations which prevent powder buildup and damage to moving parts. Vibration is particularly effective with smaller powder particles.

Step C relates to air pulsing and an air pulsor. Similar to the vibration capability, the reactor has unique air injectors mounted around the entry opening. While these can be used to independently increase air pressure in the reactor or increase the flow rate of the powder, it can also be used to prevent powder buildup. Vibration is effective against smaller powdered particles and air pulsing prevents smaller particles from building up in the reaction chamber. Buildup is important for machine runtime as well as to prevent powder from being overexposed to plasma which could destroy it or give it characteristics outside the engineered tolerances.

Step D is the heating coil and/or heatsink. The reactor can be fitted with heating coils around the reaction chamber to increase the overall plasma reaction temperature. This can impart unique characteristics such as breaking the hydrogen bonds in a protein peptide to alter the tertiary structure and denature the peptide. Conversely, a heat sink can be fitted with either passive or active cooling (depending on plasma strength) to maintain a reaction at ambient air temperature.

Step E is the humidity and/or water injector. The plasma reactor can take advantage of natural humidity to change the reaction characteristics. This has been show to incite hydrolysis in protein peptides and the degree of hydrolysis can be controlled by relative humidity or even injection water directly into the reaction when a high degree of hydrolysis is required. Conversely, an air dryer can be fitted to feed the reaction when no hydrolysis is required.

Step F is the magnetic and/or electromagnetic plasma “lens”. The use of magnetic or electromagnetic fields to contain plasma is well studied and even demonstrated in reactor designs such as a Tokamak or Stellarator reactor in fusion research. Similarly, the reactor design allows the use of a spherical magnetic field to help concentrate the plasma and mitigate plasma loss. This increases the efficiency and exposure time of the plasma without increasing the energy required to generate the plasma field.

Step G is the ultraviolet and/or pulsed light. Exposure to ultraviolet radiation or high energy pulsed light has been used for sterilization or to change the surface characteristics of a substrate. The reactor allows for both ultraviolet and pulsed light exposure during the plasma reaction or optionally this can be utilized prior or directly after plasma exposure. Currently no commercial system allows for both plasma exposure combined with PL or UV exposure inline (or simultaneously).

The treated powder and/or granules are collected in the collection tank 160 (as illustrated in FIG. 1). The treated powder and/or granules are then transferred to storage or other packaging.

It should be noted that the steps A-G and corresponding apparatus parts can be used in the order as described above or in any other suitable order.

The above method and apparatus for treating supplement powder (by surface treating and/or etching) may also be or provided to other supplements in various forms (powder, pill, tablet . . . etc.) to increase absorption characteristics.

Several of the parameters as described above may be varied to obtain a desired protein structure for the treated supplement powder. For example, the exposure time, plasma strength, plasma frequency, temperature and humidity or presence of water may all be adjusted to have a desired structural change to a protein such changes to the secondary and tertiary structures of the protein.

Some of these parameters and their interactions have a correlation with each other. For example, operating the apparatus as described above having a plasma power at 500-watts and expose for 1 second would result in a similar modified protein as operating with the plasma at 1000-watts for 0.5 of a second. However, in practice, there can be benefits to a longer exposure time allowing the plasma to permeate a very large powder granule. Other parameters such as the humidity display a more linear relationship. With no humidity, the modified protein has a very low or non-existent DH (degree of hydrolysis, or breaking down the amino chain length) whereas an increase in humidity results in an increased DH.

In one aspect, the process utilized does not thermally denature the protein. The process may include controlling the heat of the reaction or pre-warming the protein before it enters the tube to speed up the plasma reaction. For example, the process may include a 70 degree, 500-watt reaction to obtain a desired modified protein structure. Alternatively, one may pre-heat the processed powder to 80 degrees and thereafter use a 400-watt reaction to obtain a similar change to the protein structure and result in a faster throughput of the process. In one aspect, the process may include a power from 250 to 10,000W at a temperature of from 50 to 250 F at a rate of from 1/10 to 10 lbs/s.

### EXAMPLES

Whey protein powders including WPI and WPC were processed in the apparatus as described above using various parameters as will be described below.

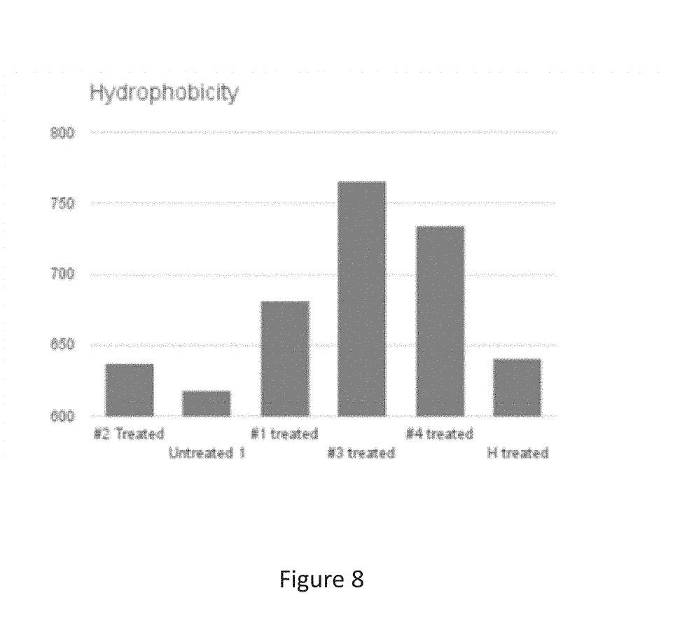

Referring to FIG. 8, there is shown a plot of the hydrophobicity by fluorescence Intensity as measured by probe Spectrofluorometry of various samples using the process as described above. The parameters for the various samples are displayed in Table A below. The change in hydrophobicity indicates a change in the protein structure in comparison to an untreated protein.

TABLE A

| Sample | Plasma Power | Exposure Time | Humidity |
|---|---|---|---|
| Untreated | 0 | 0 | 0 |
| Treated #1 | 500 W | 1 lb/s | 0 |
| Treated #2 | 250 W | 1 lb/s | 0 |
| Treated #3 | 800 W | 1 lb/s | 0 |
| Treated #4 | 750 W | 1 lb/s | 0 |
| H Treated | 250 W | 1 lb/s | 25% |

As can be seen in the plot, adjusting the process parameters results in an increased hydrophobicity in comparison to the untreated sample indicating a change to the protein structure.

Whey protein powders including WPI and WPC were processed in the apparatus as described above using various parameters as will be described below.

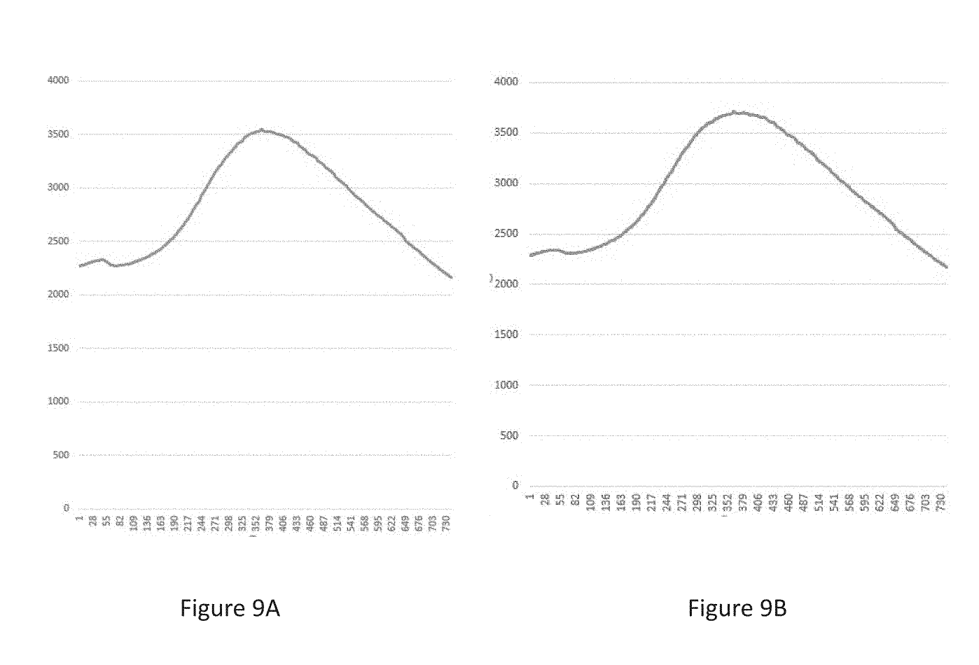

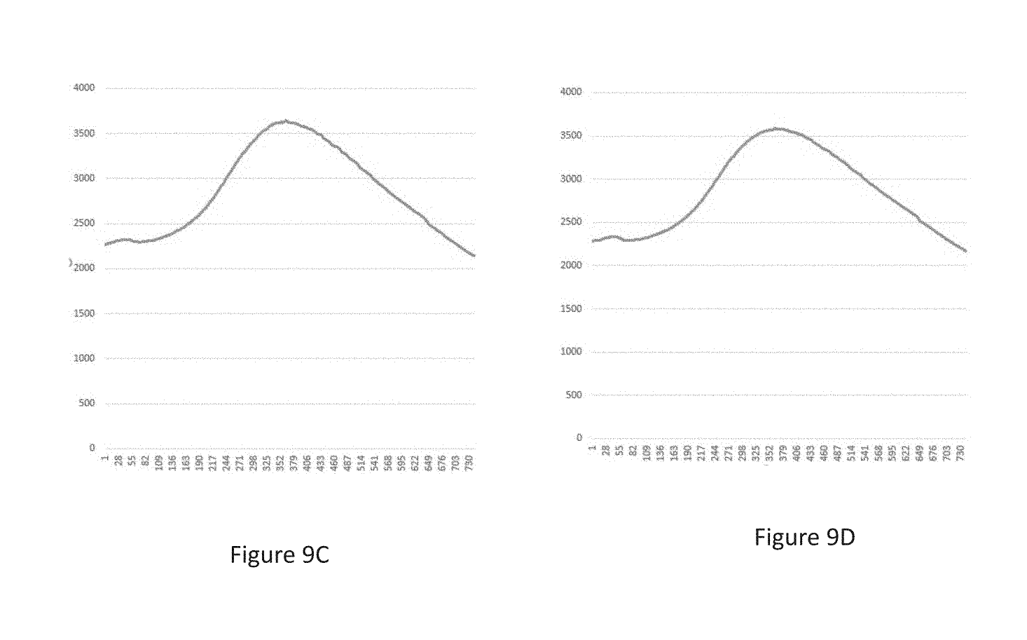

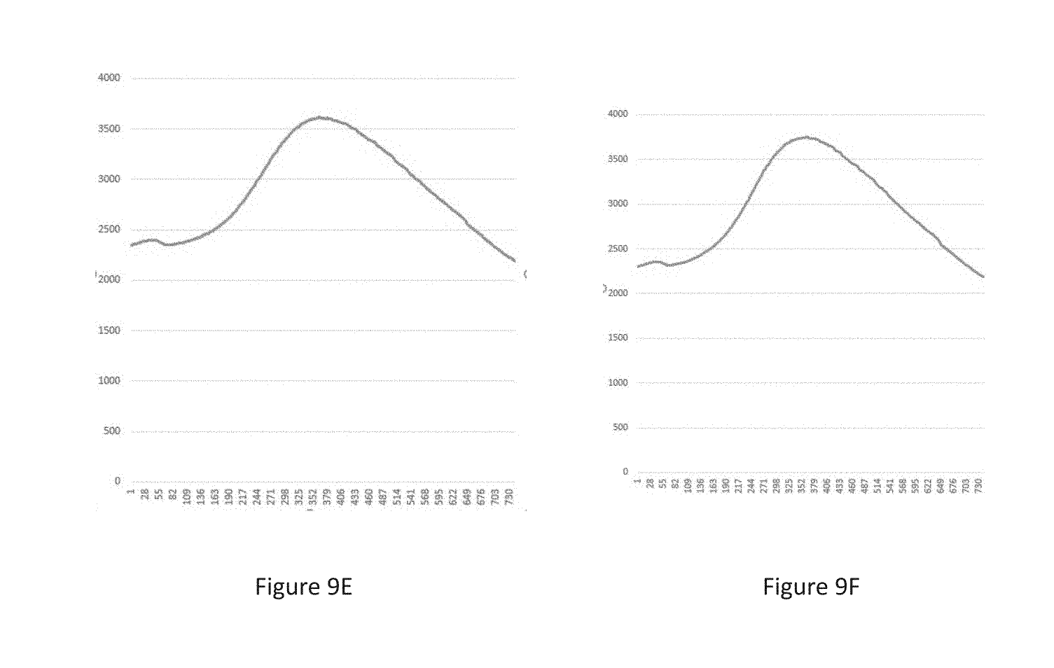

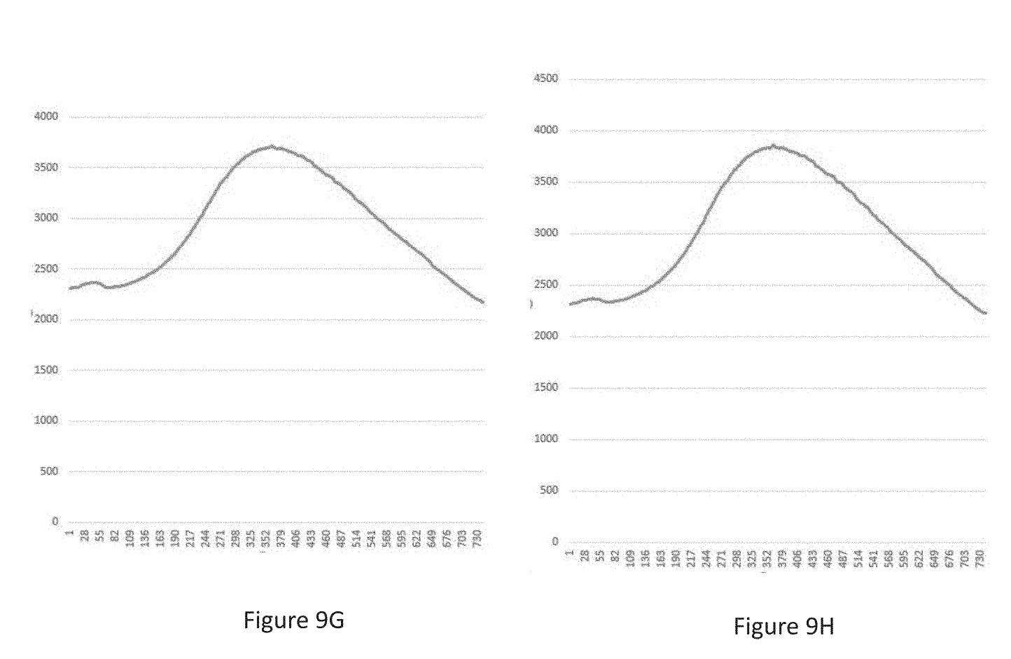

Referring to FIGS. 9A-H, there are shown melt curves of the proteins with the fluorescence Intensity on the Y-axis as a function of temperature with the scale 1 representing 25 C and 750 representing 99 C. The parameters for the various samples are displayed in Table B below. The change in melt curve value at various temperatures indicates a change in the protein structure in comparison to an untreated protein.

TABLE B

| | Plasma | Exposure | | Temperature |
|---|---|---|---|---|
| Sample | Power | Time | Humidity | (F.) |
| Untreated | 0 | 0 | 0 | |
| (FIG. 9A) | | | | |
| Treated #1 | 300 W | 1 lb/s | 0 | Room |
| (FIG. 9B) | | | | |
| Treated #2 | 500 W | 1 lb/s | 0 | Room |
| (FIG. 9C) | | | | |
| Treated #3 | 750 W | 1 lb/s | 0 | Room |
| (FIG. 9D) | | | | |
| Treated #4 | 1000 W | 1 lb/s | 0 | Room |
| (FIG. 9E) | | | | |
| Treated #5 | 1000 W | 1 lb/s | 0 | 150 |
| (FIG. 9F) | | | | |
| Treated #6 | 1000 W | 1 lb/s | 0 | 200 |
| (FIG. 9G) | | | | |
| Treated #7 | 1000 W | 1 lb/s | 0 | 250 |
| (FIG. 9H) | | | | |

As can be seen in the plots, the fluorescence Intensity increases with an increase in power and temperature. All of the treated samples have intensity greater than 2041 at room temperature.

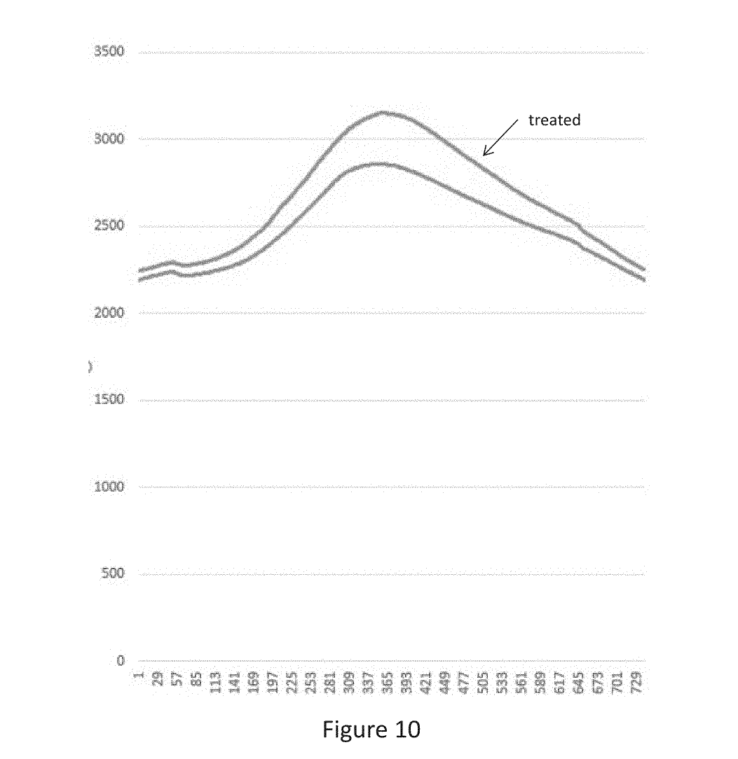

Referring to FIG. 10, there are shown melt curves of WPI proteins with the fluorescence Intensity on the Y-axis as a function of temperature with the scale 1 representing 25 C and 750 representing 99 C. The treated protein was processed at room temperature (25 C) at a power of 1000 W with a throughput of 1 lbs/s. As can be seen in the plot, the treated sample has an increase in fluorescence Intensity over the entire temperature range of the plot. The change in melt curve value at various temperatures indicates a change in the protein structure in comparison to an untreated protein.

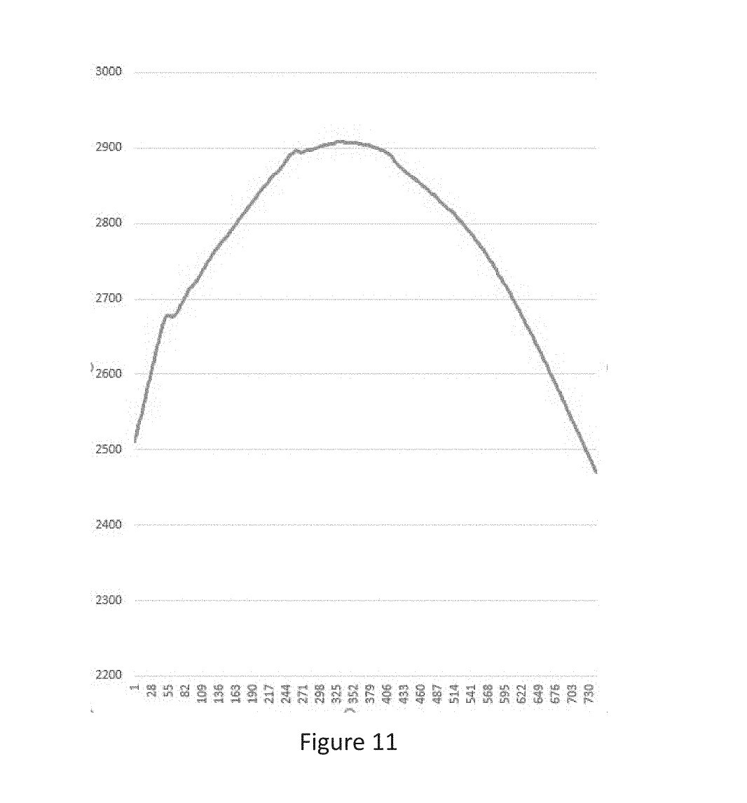

Referring to FIG. 11, there is shown a are shown melt curves of WPI protein with the fluorescence Intensity on the Y-axis as a function of temperature with the scale 1 representing 25 C and 750 representing 99 C. The treated protein was processed at room temperature at a power of 1000 W with 25% humidity with a throughput of 1 lbs/s. As can be seen in the plot, the treated sample has an increase in fluorescence Intensity over the entire temperature range of the plot. The change in melt curve value at various temperatures indicates a change in the protein structure in comparison to an untreated protein. The treated samples have intensity greater than 1955 at room temperature.

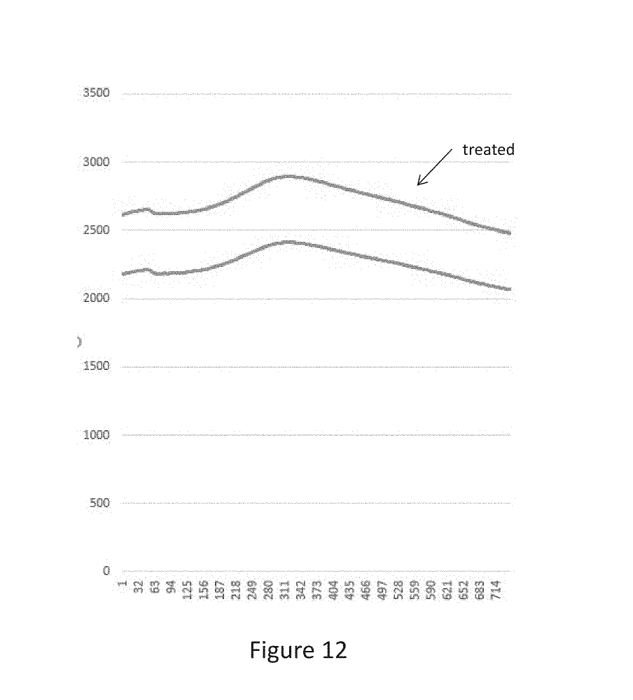

Referring to FIG. 12, there are shown melt curves of Casein proteins with the fluorescence Intensity on the Y-axis as a function of temperature with the scale 1 representing 25 C and 750 representing 99 C. The treated protein was processed at room temperature at a power of 1000 W with a throughput of 1 lbs/s. As can be seen in the plot, the treated sample has an increase in fluorescence Intensity over the entire temperature range of the plot. The change in melt curve value at various temperatures indicates a change in the protein structure in comparison to an untreated protein. The treated samples have intensity greater than 2177 at room temperature.

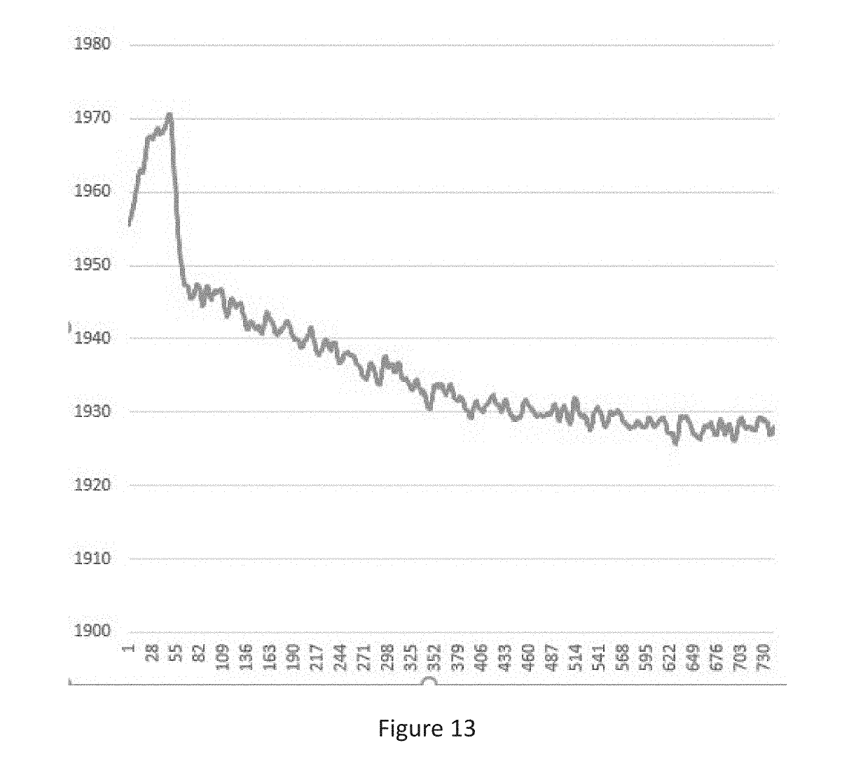

Referring to FIG. 13, there are shown melt curves of treated Soy protein with the fluorescence Intensity on the Y-axis as a function of temperature with the scale 1 representing 25 C and 750 representing 99 C. The treated protein was processed at room temperature at a power of 1000 W with a throughput of 1 lbs/s. The change in melt curve value at various temperatures indicates a change in the protein structure in comparison to an untreated protein. The treated samples have intensity greater than 2255 at room temperature.

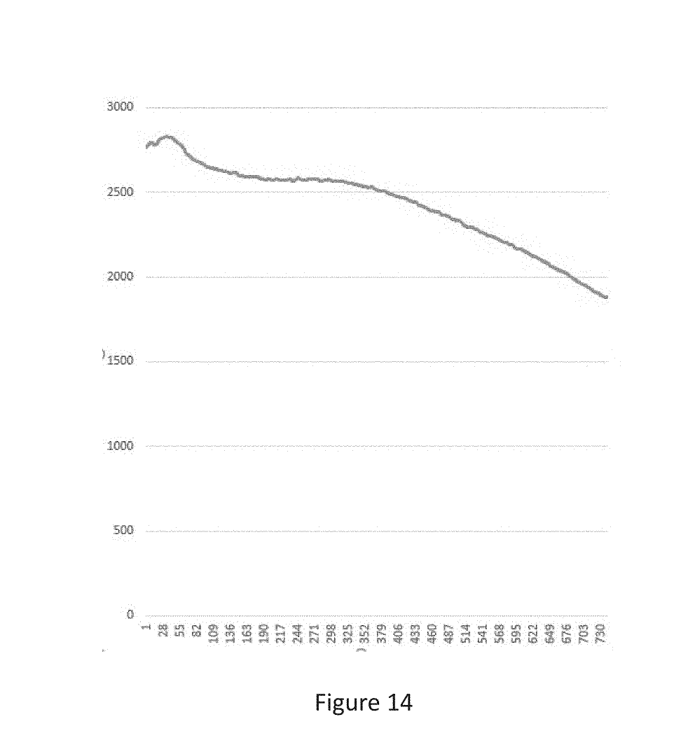

Referring to FIG. 14, there are shown melt curves of treated Sacha Inchin protein with the fluorescence Intensity on the Y-axis as a function of temperature with the scale 1 representing 25 C and 750 representing 99 C. The treated protein was processed at room temperature at a power of 1000 W with a throughput of 1 lbs/s. The change in melt curve value at various temperatures indicates a change in the protein structure in comparison to an untreated protein. The treated samples have intensity greater than 2362 at room temperature.

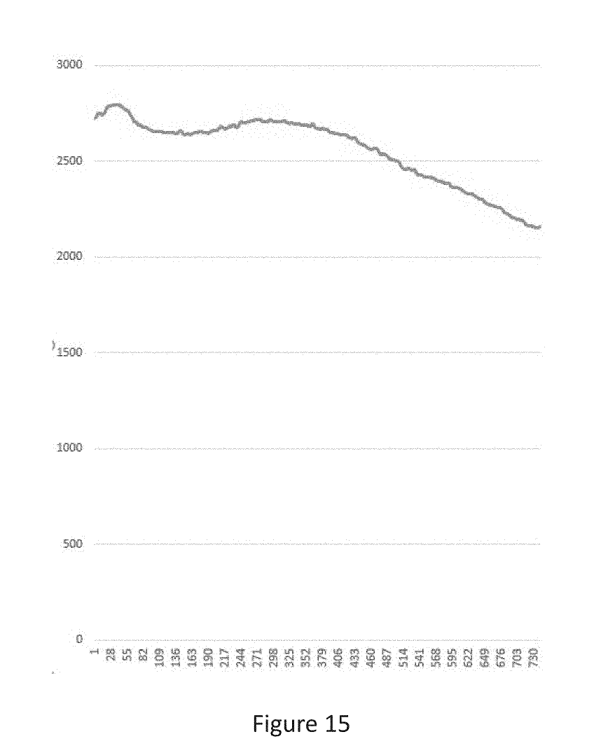

Referring to FIG. 15, there are shown melt curves of treated Rice protein with the fluorescence Intensity on the Y-axis as a function of temperature with the scale 1 representing 25 C and 750 representing 99 C. The treated protein was processed at room temperature at a power of 1000 W with a throughput of 1 lbs/s. The change in melt curve value at various temperatures indicates a change in the protein structure in comparison to an untreated protein. The treated samples have intensity greater than 2426 at room temperature.

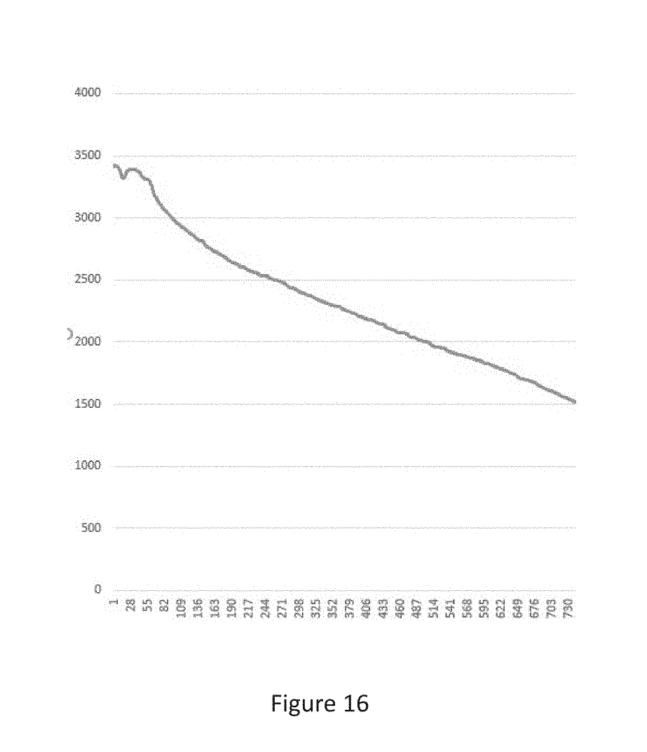

Referring to FIG. 16, there are shown melt curves of treated Pea protein with the fluorescence Intensity on the Y-axis as a function of temperature with the scale 1 representing 25 C and 750 representing 99 C. The treated protein was processed at room temperature at a power of 1000 W with a throughput of 1 lbs/s. The change in melt curve value at various temperatures indicates a change in the protein structure in comparison to an untreated protein. The treated samples have intensity greater than 3111 at room temperature.

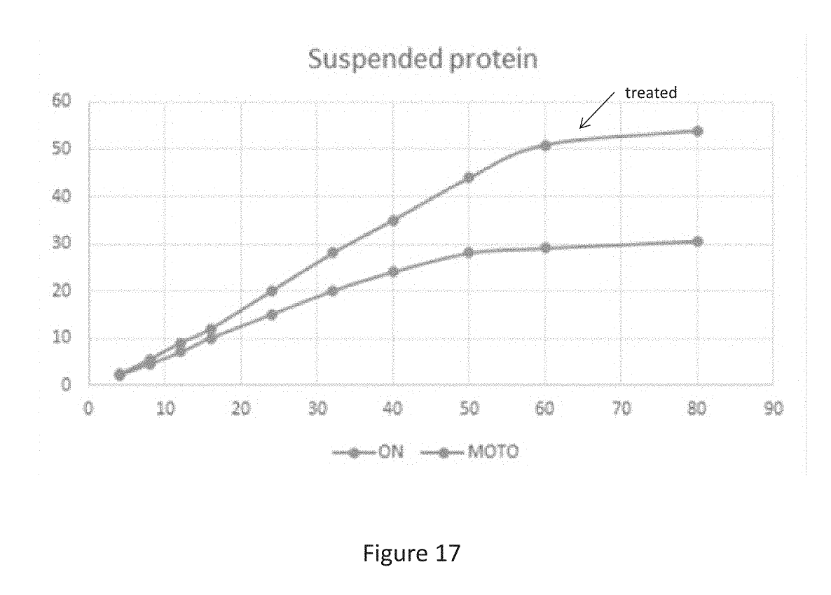

Referring to FIG. 17, there are shown plots of the solubility of a treated protein (MOTO) in comparison to an untreated sample. The treated protein was a WPI-90 protein that was processed at a temperature of from 80 F with a plasma power of 800 W at a through put of 1 lb/s. FIG. 17, displays how much protein is ‘suspended’. The plots were generated by briefly shaking different amounts of protein into water, simulating use by a consumer, and then lightly centrifuging the samples to remove the large debris. The x-axis indicates the amount of protein in, and the y-axis displays Maximum solubility percentage. A straight line going from 0 to 100 on both axes would indicate 100% solubility. As can be seen, the treated protein sample over performs at low levels, but also has a much higher peak. The water is able to take up more treated protein before the protein peaks.

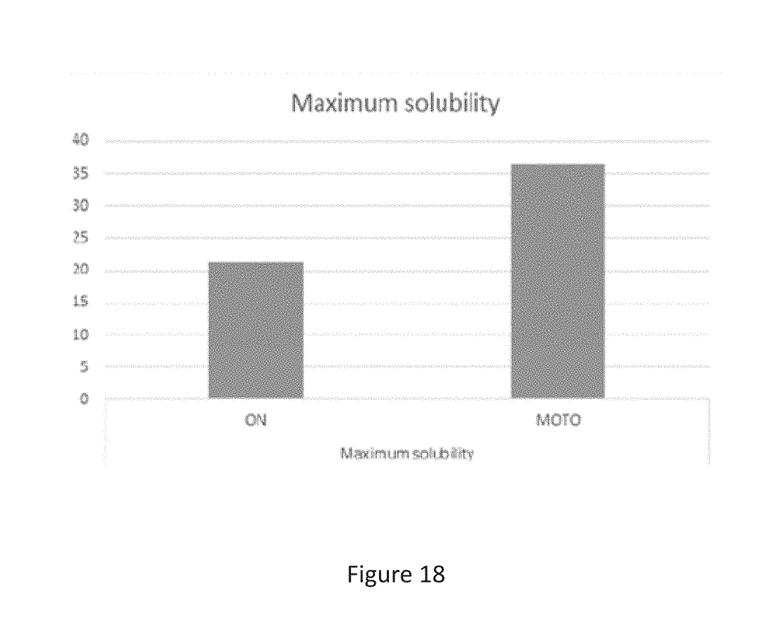

Referring to FIG. 18, the water can dissolve over 150% more treated protein in comparison to the un-treated, sample. The treated protein is completely dissolved, and not particulate or clumped to any degree indicating an increased amount of bioavailability and access for digestive enzymes. The untreated solubility is 21% whereas the treated sample has a solubility of greater than 35%.

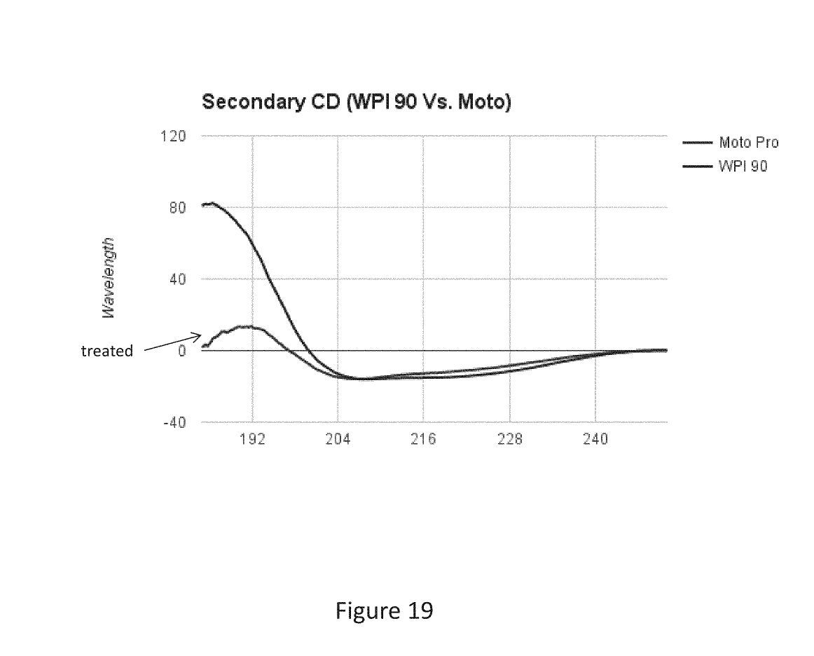

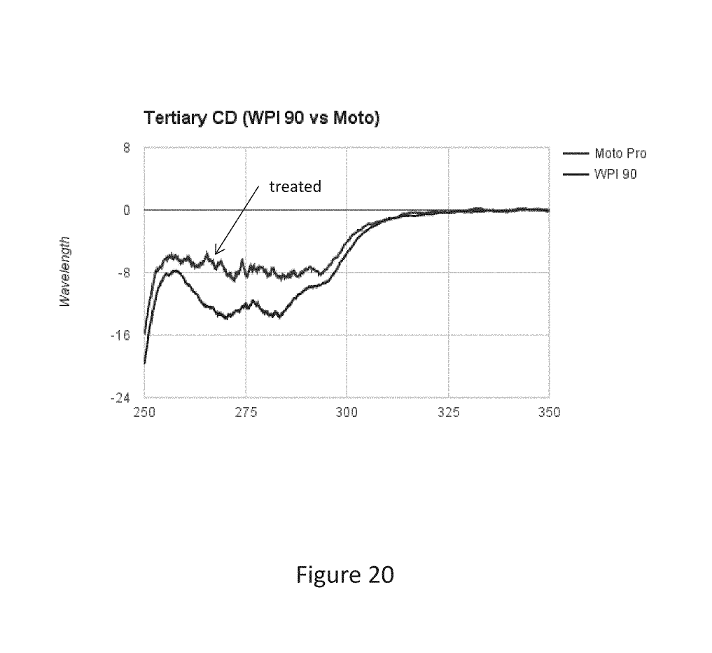

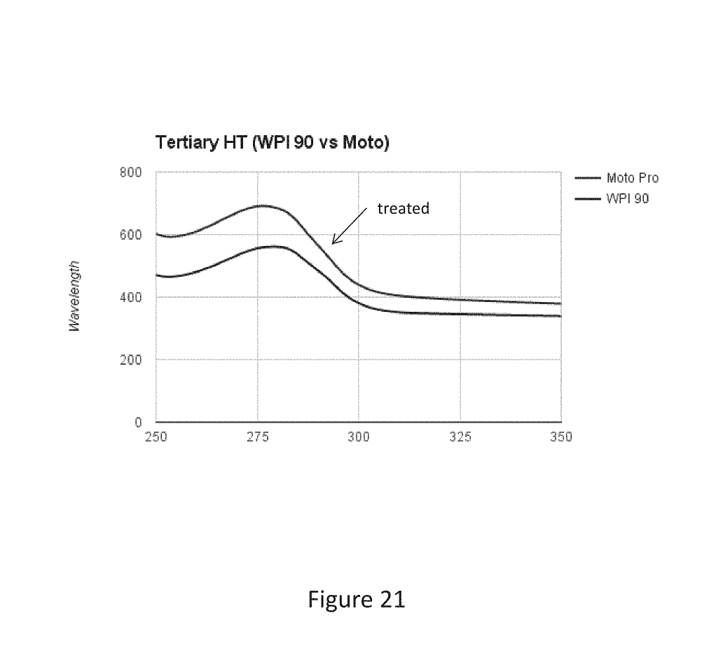

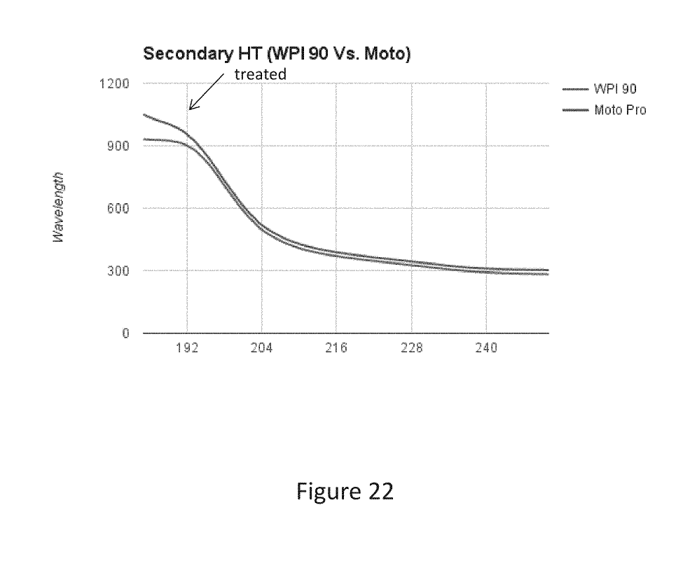

Referring to FIGS. 19-22 there are displayed Circular dichroism (CD) plots showing secondary and tertiary structure changes to the protein in comparison to an untreated WPI protein. The treated protein was a WPI protein that was processed at a temperature of from 80-100 degrees F. with a plasma power of 750-1000W at a through put of 1 lb/s. The plots include an x-axis that is wavelength and y-axis that is ellipticity. The plots demonstrate a change in the secondary and tertiary structure of the treated protein sample.

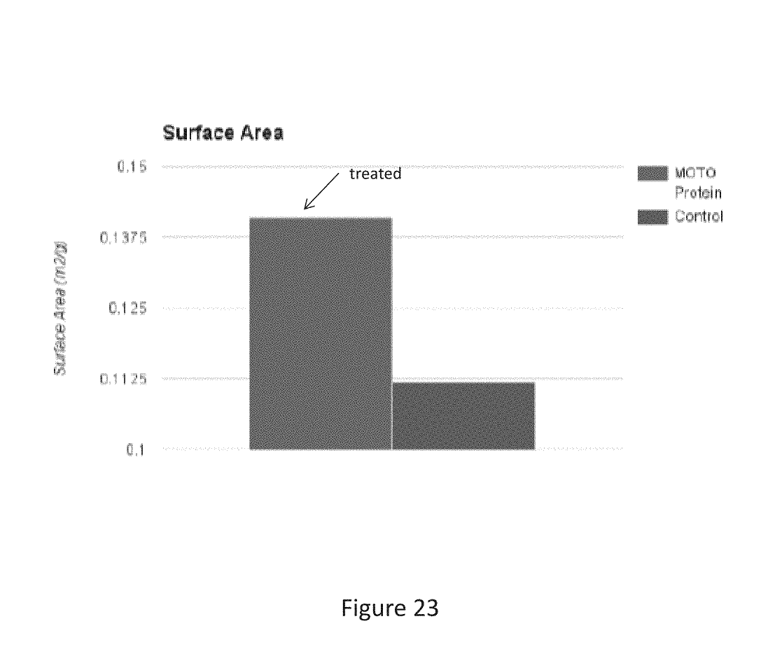

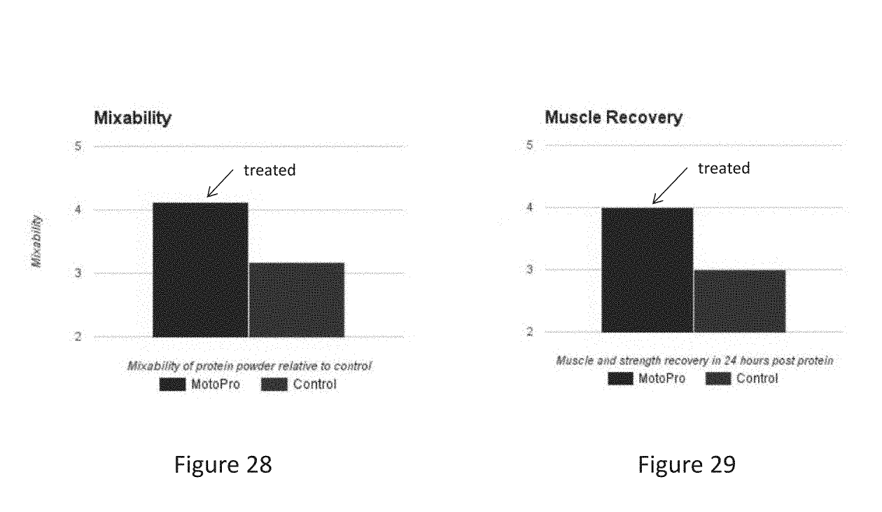

Referring to FIG. 23-31 there are displayed various parameters detailing the results of a randomized study of 20 well trained young adult males including IFBB and pre-Olympic competitors having a mean age of 28. The subjects were divided into two groups with one group taking a treated protein supplement and the other group taking an untreated supplement. The diet exercise regimen and supplement consumption was logged daily for each participant. Dual energy x-ray absorptiometry was utilized to measure test subjects at the start and conclusion of the study.

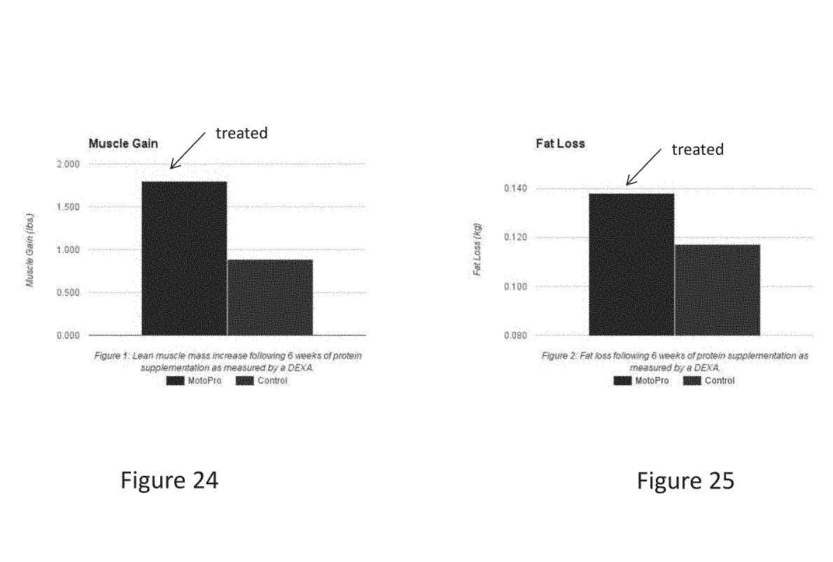

The treated protein was a WPI protein that was processed at a temperature of from 80-100 degrees F. with a plasma power of 750-1000 W at a through put of 1 lb/s. As can be seen in FIG. 23, the treated protein includes a significantly higher surface area in comparison to the un-treated sample indicating a higher bioavailability. As shown in FIGS. 24-25, subjects taking the treated protein experienced a clinically and statistically significant 204% increase in lean muscle mass and an 18% increase in fat loss in comparison to the uprocessed whey protein.

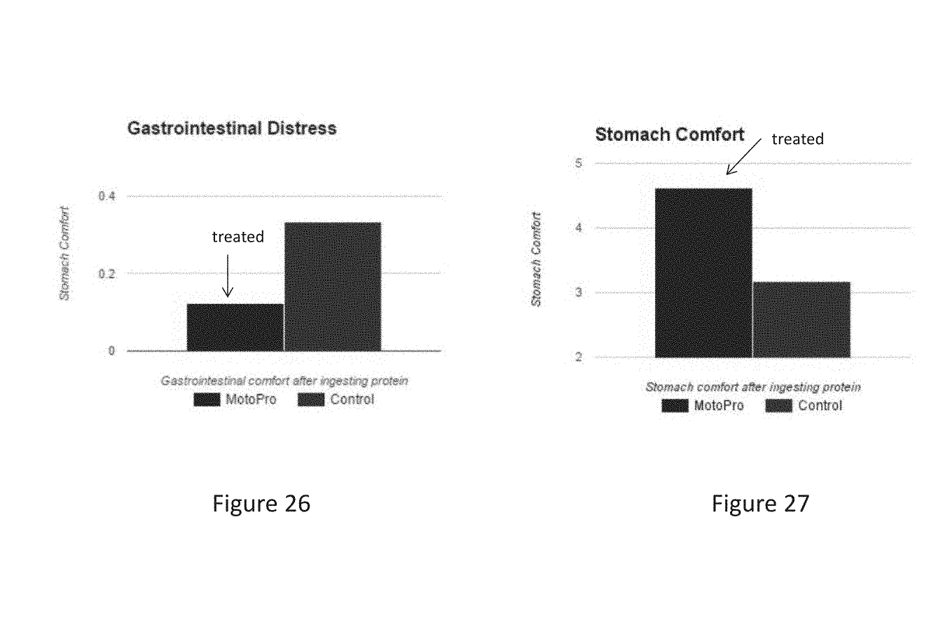

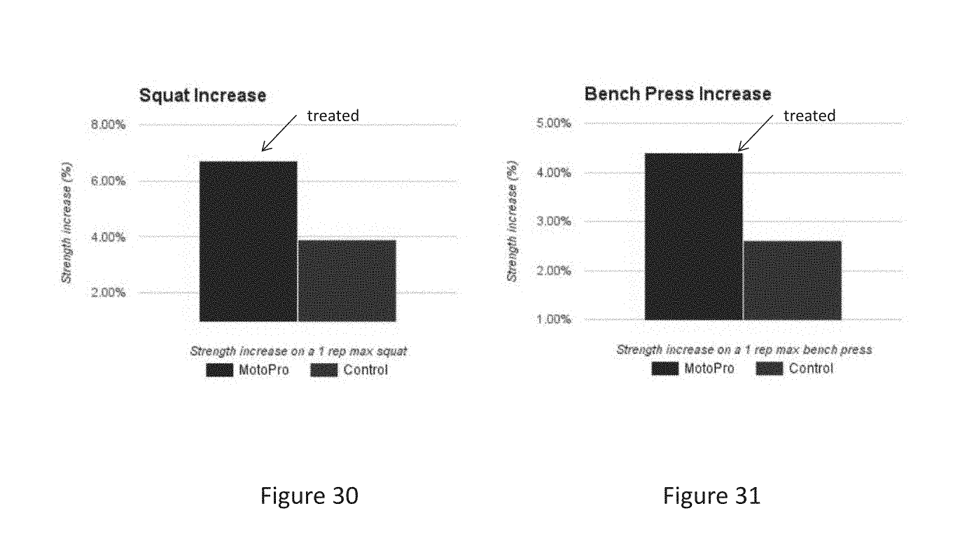

Referring to FIGS. 26-30 there are shown plots detailing the digestibility, mixability and muscle recovery for processed and un-processed samples as described above. Subjects taking the treated protein experienced a clinically and statistically significant 62.50% reduction in gastrointestinal distress, 46.05% improvement in stomach comfort, 30.26% improvement in mixability and a 33% increase in muscle recovery time when compared to the un-processed whey protein. Referring to FIGS. 30 and 31, there are shown plots detailing the strength characteristics of a subject taking the treated and un-treated proteins. As can be seen in the plots, subjects taking the treated protein had a clinically and statistically significant 172.64% increase in bench press strength and a 170.85% increase in squat strength in comparison to an untreated protein.

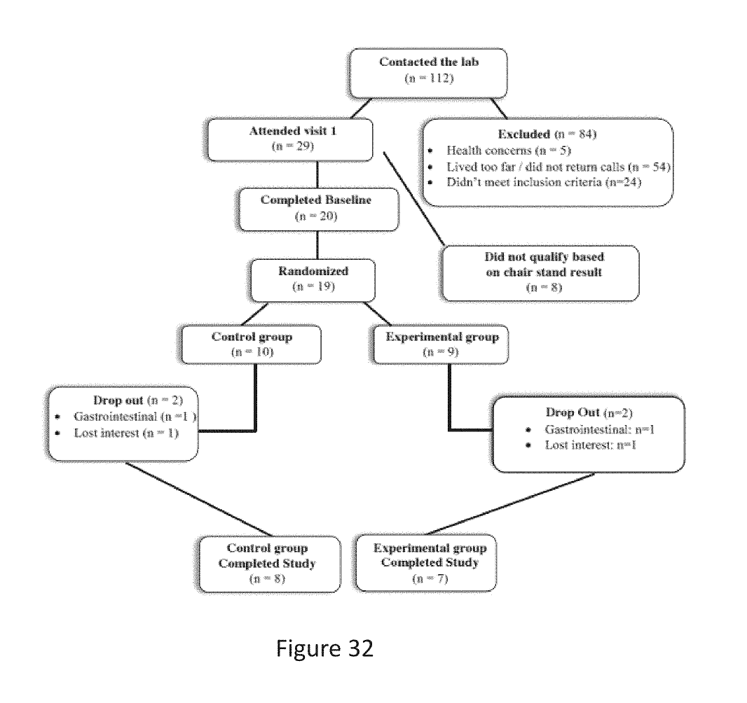

Another study was performed with an older population of adults to determine the effects of the treated proteins ingested by humans. A total of 19 individuals were randomized to one of two groups in a 12 week study in which 15 completed the study. Seven individuals were in an experimental group receiving a treated protein and eight individuals were in a control group. A graphical representation of the study parameters are displayed in FIG. 32. The treated protein was a WPI protein that was processed at a temperature of from 80-100 degrees F. with a plasma power of 750-1000 W at a through put of 1 lb/s. The untreated or control group was given a WPI protein.

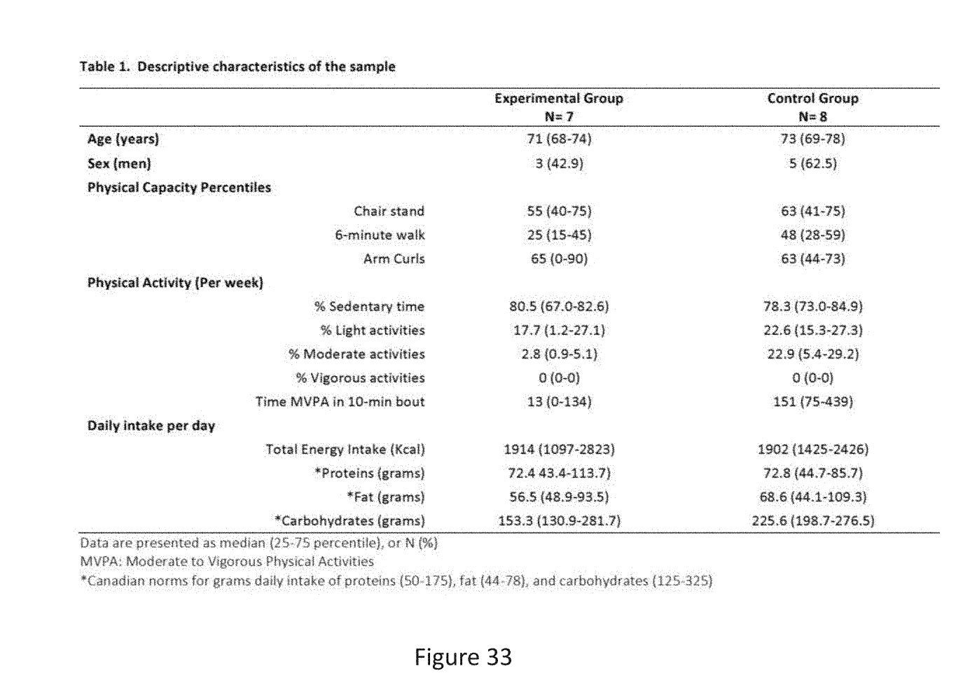

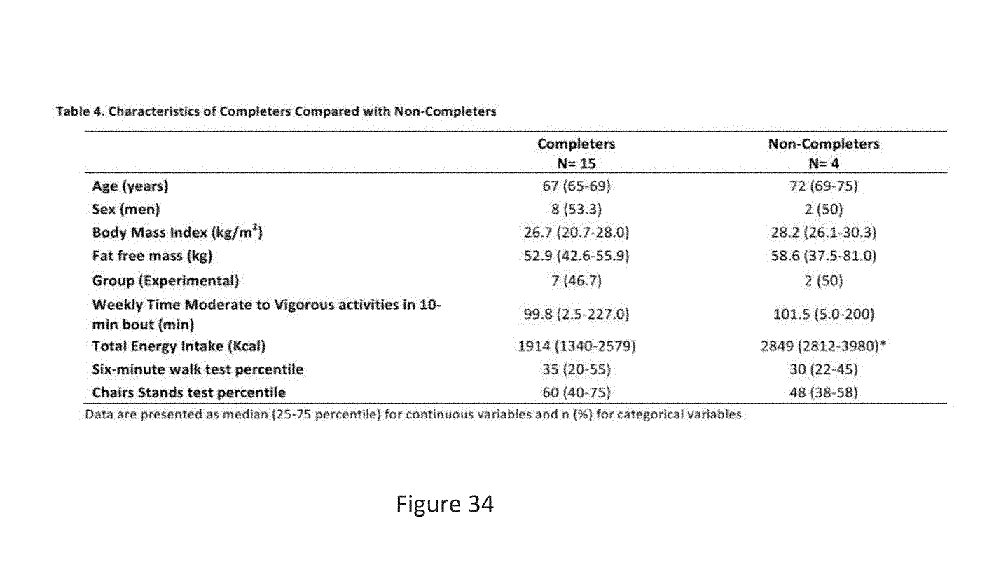

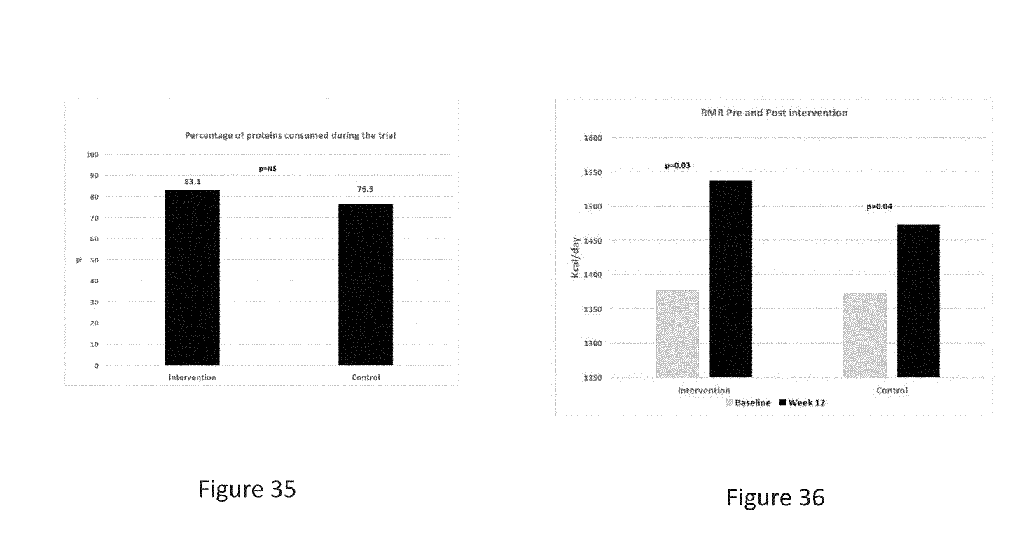

Tables 1 and 4 presented in FIGS. 33 and 34 detail the characteristics of the control and experimental groups at 6 week intervals for the study. Graphical representations of the percentage of proteins consumed for the study and the Resting Metabolic Rate (RMR) are provided for the experimental and control groups in FIGS. 35 and 36 respectively. As be seen from the figures, the experimental group showed an increase in the amount of proteins consumed in comparison to the control group. Additionally, the experimental group showed a much larger increase in RMR from the start of the study to week 12 in comparison to the control group.

In another study, 32 resistance-trained males (22.2±4.3 years; 177.3±7.8 cm; 77.6±12.6 kg) participated in this randomized, double-blinded investigation. Participants were matched according to FFM and randomized to the Standard WPI (n=18) or the Novel WPI (n=14). The Standard WPI group was provided with 27 g of WPI per serving and the Treated WPI group was given a reduced volume of WPI (20 g of uniquely treated WPI+7 g maltodextrin to match the volume of the Standard WPI serving size). Both protein supplements were taken daily, including immediately after each training session (4×/week). The treated protein was a WPI protein that was processed at a temperature of from 80-100 degrees F. with a plasma power of 750-1000 W at a through put of 1 lb/s. Both groups performed the same training program, and maintained a protein intake of 1.5-2.5 g/kg/d to facilitate recovery from and adaptation to training. At baseline and following 8-week training program, participants were assessed for maximal strength on the back squat, bench press, and deadlift. The program consisted of two lower-body and two upper-body workouts/week for an 8-week period.

Data were analyzed via a 2-factor [2×2] between-subjects repeated measures ANOVA and pre to post changes within each group were analyzed by a paired-samples t-test. The alpha criterion for significance set at 0.05.

No differences existed between the two groups for strength measures at baseline. The repeated measures ANOVA revealed a main effect for time for the back squat (p<0.001), bench press (p<0.001), and deadlift (p<0.001) exercises, but no group x time interactions were observed for absolute or relative strength between groups.

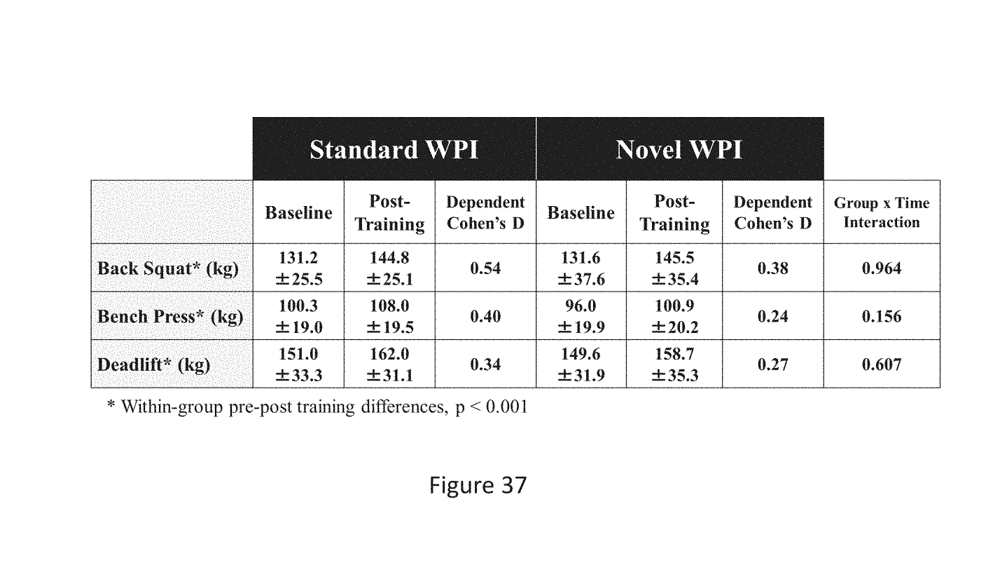

Specifically, back squat increased from 131.2±25.5 kg to 144.8±25.1 kg (improvement of 10.4%) and from 131.6±37.6 kg to 145.5±35.4 kg (improvement of 10.6%); bench press increased from 100.3±19.0 kg to 108.0±19.5 kg (improvement of 7.7%) and from 96.0±19.9 kg to 100.9±20.2 kg (improvement of 5.1%); deadlift increased from 151.0±33.3 kg to 162.0±31.1 kg (improvement of 7.3%) and from 149.6±31.9 kg to 158.7±35.3 kg (improvement of 6.1%) in the Standard WPI and Treated WPI groups, respectively. Data regarding the study is displayed in FIG. 37.

In resistance-trained males, using a reduced amount (25% less WPI) of treated WPI as a post-workout protein supplement elicits the same increases in strength as a higher-protein dosed, standard WPI supplement.

Additionally, the same study participants were also accessed for body composition. 32 resistance-trained males (22.2±4.3 years; 177.3±7.8 cm; 77.6±12.6 kg) participated in this randomized, double-blinded investigation. Participants were matched according to fat-free mass (FFM) and randomized to the Standard WPI (n=18) or the Novel WPI (n=14). The Standard WPI group was provided with 27 g of WPI per serving and the treated WPI group was given a reduced volume of WPI (20 g of uniquely processed WPI+7 g maltodextrin to match the volume of the Standard WPI serving size) immediately after each resistance training session (4×/week). At baseline and following 8-weeks of training, participants were assessed for body composition (FFM, dry lean mass [DLM], fat mass [FM], and bodyfat percentage [BF%]). The resistance-training program consisted of two lower-body and two upper-body workouts/week for 8 weeks. Data were analyzed via a 2-factor [2×2] between-subjects repeated measures ANOVA and pre to post changes within each group were analyzed by a paired-samples t-test.

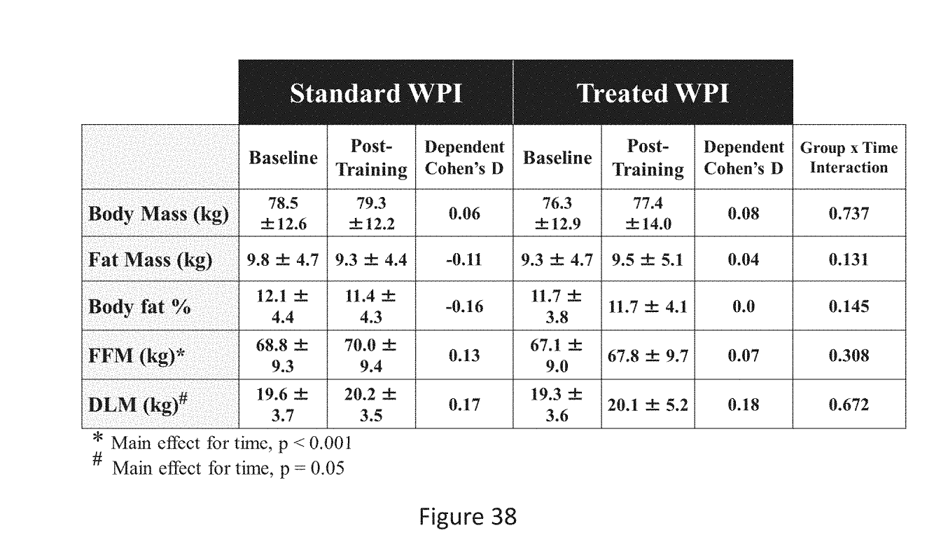

No differences existed between the two groups for body composition measures at baseline. The repeated measures ANOVA revealed a main effect for time for FFM (p<0.001) and DLM (p=0.05), but no group x time interactions. Specifically, FFM increased from 68.8±9.3 kg to 70.0±9.4 kg and from 67.1±9.0 kg to 67.8±9.7 kg; DLM increased from 19.6±3.7 kg to 20.2±3.5 kg and from 19.3±3.6 kg to 20.1±5.2 kg in the Standard WPI and treated WPI groups, respectively. The paired samples t-test revealed a significant increase in FFM over time in the Standard WPI group (p=0.001) and a trend for significance in the treated WPI group (p=0.082). However, when body water was accounted for (DLM), neither group significantly increased DLM over time (Standard WPI: p=0.164; Novel WPI: p=0.185). There were no main effects for time nor a group x time interaction for FM and BF% (p>0.05). Data regarding the study is displayed in FIG. 38.

In resistance-trained males, using a reduced amount (25% less WPI) of treated processed WPI as a post-workout protein supplement elicits changes in body composition similar to using a higher-protein dosed, standard WPI supplement.

It is noted that the terms “substantially” and “about” may be utilized herein to represent the inherent degree of uncertainty that may be attributed to any quantitative comparison, value, measurement, or other representation. These terms are also utilized herein to represent the degree by which a quantitative representation may vary from a stated reference without resulting in a change in the basic function of the subject matter at issue.

While particular embodiments have been illustrated and described herein, it should be understood that various other changes and modifications may be made without departing from the spirit and scope of the claimed subject matter. Moreover, although various aspects of the claimed subject matter have been described herein, such aspects need not be utilized in combination. It is therefore intended that the appended claims cover all such changes and modifications that are within the scope of the claimed subject matter.

1. A plasma treated orally ingested protein powder composition comprising:
a protein powder exposed to plasma at a specified temperature and power for a specified time period wherein the plasma treated protein powder includes an increased fluorescence in a melt curve at room temperature in comparison to an untreated protein.

2. The protein powder composition of claim 1 wherein the protein is selected from Whey, Casein. Soy, Sacha Inchin, Rice and Pea.

3. The protein powder composition of claim 1 wherein the treated protein is WPI and has fluorescence greater than 2041 at room temperature or 25 degrees C.

4. The protein powder composition of claim 1 wherein the treated protein is Caesin and has fluorescence greater than 2177 at room temperature or 25 degrees C.

5. The protein powder composition of claim 1 wherein the treated protein is Soy and has fluorescence greater than 2255 at room temperature or 25 degrees C.

6. The protein powder composition of claim 1 wherein the treated protein is WPI at 25% humidity and has fluorescence greater than 1955 at room temperature or 25 degrees C.

7. The protein powder composition of claim 1 wherein the treated protein is Pea and has fluorescence greater than 3111 at room temperature or 25 degrees C.

8. The protein powder composition of claim 1 wherein the treated protein is Sacha Inchin and has fluorescence greater than 2362 at room temperature or 25 degrees C.

9. The protein powder composition of claim 1 wherein the treated protein is Rice and has fluorescence greater than 2426 at room temperature or 25 degrees C.

10. The protein powder composition of claim 1 wherein the treated protein is Whey and has hydrophobicity greater than 620.

11. The protein powder composition of claim 1 wherein the treated protein is Whey and includes solubility greater than 22%.

12. The protein powder composition of claim 1 wherein the treated protein is Whey and includes a surface area greater than 0.1125 m²/g.

13. The protein powder composition of claim 1 wherein the plasma treated protein powder is Whey and is formed from exposure of a protein powder to plasma of from 750 to 10,000 W at a temperature of from 80 to 250 F at a rate of from 1/10 to 10 lbs/s.

14. A plasma treated orally ingested protein powder composition comprising:
a protein powder exposed to plasma at a specified temperature and power for a specified time period wherein the plasma treated protein powder includes an increased fluorescence in a melt curve at room temperature in comparison to an untreated protein for use in the improvement of a muscle function in a mammal.

15. The protein powder composition of claim 14 wherein the treated protein is WPI and has fluorescence greater than 2041 at room temperature or 25 degrees C.

16. The protein powder composition of claim 14 wherein the muscle function is skeletal muscle function.

17. The protein powder composition of claim 16 wherein improving skeletal muscle function comprises improving muscle mass and improving strength.

18. The protein powder composition of claim 14 wherein the plasma treated protein powder is WPI and includes solubility greater than 22%.

19. The protein powder composition of claim 14 wherein the plasma treated protein powder is WPI and includes a surface area greater than 0.1125 m²/g.

20. The protein powder composition of claim 14 wherein the plasma treated protein powder is formed from exposure of a protein powder to plasma of from 750 to 10,000 W at a temperature of from 80 to 250 F at a rate of from 1/10 to 10 lbs/s.

21. A method of increasing muscle protein comprising administering to a subject a protein powder exposed to plasma at a specified temperature and power for a specified time period wherein the plasma treated protein powder includes wherein the plasma treated protein powder includes an increased fluorescence in a melt curve at room temperature in comparison to an untreated protein.

22. The method of claim 21 wherein the treated protein is WPI and has fluorescence greater than 2041 at room temperature or 25 degrees C.

23. The method of claim 21 wherein the treated protein is WPI and has hydrophobicity greater than 620.

24. The method of claim 21 wherein the plasma treated protein powder includes solubility greater than 22%.

25. The method of claim 21 wherein the plasma treated protein powder includes a surface area greater than 0.1125 m²/g.

26. The method of claim 21 wherein the plasma treated protein powder is formed from exposure of a protein powder to plasma of from 750 to 10,000 W at a temperature of from 80 to 250 F at a rate of from 1/10 to 10 lbs/s.
